(19) United States
(12) Patent Application Publication
(10) Pub. No.: US 2002/0035552 A1
(43) Pub. Date: Mar. 21, 2002

(54) Automatic charge collection system, and automatic charge collecting terminal for use in the system

(75) Inventor: Shuichi Tsubura, Maebashi (JP)

Correspondence Address: ARMSTRONG,WESTERMAN & HATTORI, LLP, 1725 K STREET, NW., SUITE 1000, WASHINGTON, DC, 20006, US

(73) Assignee: FUJITSU LIMITED, Kawasaki (JP)

(21) Appl. No.: 09/820,981

(22) Filed: Mar. 30, 2001

(30) Foreign Application Priority Data
Sep. 4, 2000 (JP) 2000-267052

(51) Int. Cl. G01R 11/56; G06F 17/00; G01R 21/133

(52) U.S. Cl. 705/412

(57) ABSTRACT

A system for automatically collecting charges in accordance with individual consumptions of a source from one or more users, the system including one or more user's mediums, provided one for each of the users, for storing electronic money, a source consumption monitor for monitoring the source consumptions for the individual users and a charge collector for collecting the charges in accordance with the individual source consumptions, which are monitored by the source consumption monitor, from the respective user's mediums as corresponding equivalent amounts of electronic money. With this system capable of automatically collecting a charge, a charge in accordance with source consumption is automatically collected.

### BACKGROUND OF THE INVENTION

1. Field of the Invention

The present invention relates to a system and a terminal for automatically collecting a charge in accordance with consumption of a source, such as water or electricity.

2. Description of the Related Art

In a conventional collection method of a utility charge for water, electricity, or etc., a reader (an inspector) of a meter periodically (e.g., monthly) checks an amount of consumed source to make a payment request slip. Then a bill for the consumption of the source is issued based on the payment request slip, and the payment for the source is made every period by a charge collection of a collector, a direct debit, or etc.

However, in this case, if a payer (user) happens to have an insufficient amount of money upon a collection of the charge for the source consumption, the payment for the source is unsuccessfully made.

Meanwhile, when the user moves to another place, it is required various procedures, such as stopping and starting providing service, or setting a manner of a payment for the service, even if the payment for the source consumption is carried out by making a monthly direct debit. Therefore such conventional collection method tends to result in a great amount of labor of both the user and a service provider.

Further, in the conventional methods, partly since it is difficult for a user of a source to grasp the source consumption, partly since the user tends to over-use the source, it is hard to avoid saving on the source consumption and preventing the source from over-use.

It is also required an appropriate method for collecting a charge in accordance with a source (e.g., water, electricity) whose amount is consumed by a guest in a hotel or a weekly rental condominium.

### SUMMARY OF THE INVENTION

With foregoing problems in view, it is an object of the present invention to provide a system and a terminal for automatically collecting charges in accordance with consumption of a source.

To attain the above-mentioned object, according to a first generic feature of the present invention, there is provided a system for automatically collecting charges in accordance with individual consumptions of a source from one or more users, the system comprising: one or more user's mediums, provided one for each of the users, for storing electronic money, which is defined as an electronic alternative to a currency; a source consumption monitor for monitoring the source consumptions for the individual users; and a charge collector for collecting the charges in accordance with the individual source consumptions, which are monitored by the source consumption monitor, from the respective user's mediums as corresponding equivalent amounts of electronic money.

With this system, it is possible for the source provider to surely collect charges in accordance with the individual source consumptions by collecting the charge from the respective user's mediums as corresponding equivalent amounts of electronic money.

Further, according to a second generic feature, there is provided a terminal for automatically collecting charges in accordance with consumptions of a source from one or more users, wherein the terminal is communicably connected with one or more user's mediums, provided one for each of the users, for storing electronic money, which is defined as an electronic alternative to a currency, and the terminal is equipped with a charge collector for collecting the charges in accordance with the individual source consumptions from the respective user's mediums as corresponding equivalent amounts of electronic money.

With this terminal, it is possible for the source provider to surely collect charges in accordance with the individual source consumptions by collecting the charge from the respective user's mediums as corresponding equivalent amounts of electronic money.

As a preferable feature, the charge collector may collect the charges in accordance with the individual source consumptions, which are monitored by the source consumption monitor, from the respective user's mediums at any time as required.

With this system, it is possible for a provider of the source to surely collect the charges in accordance with the individual source consumption also by collecting the charges from the respective user's mediums as corresponding equivalent amounts of electronic money at any time as required.

As another preferable feature, upon the collection of the charges by the charge collector, if one of the charges in accordance with the source consumption is not collected from one of the user's mediums, the charge collector may stop providing a user provided the corresponding user's medium with the source.

With this system, if the charge in accordance with the source consumption is not collected from one of the user's mediums upon the collection of the charges by the charge collector, it is possible for the source provider to avoid damages caused from the unsuccessful payment from one of the user's mediums by stopping providing the corresponding user with the source.

As still another preferable feature, the source consumption monitor may monitor amounts of source consumed by the individual users; and the charge collector may calculate the charges based on the amounts of the consumed source and previously set unit price for the source, and collects the calculated charges from respective user's mediums.

With this system, it is possible for the source provider to surely collect charges in accordance with the individual source consumptions by collecting the charge from the respective user's mediums as corresponding equivalent amounts of electronic money.

As a further preferable feature, the charge collector may include a unit price setting area in which the unit price is set from external means of the charge collector.

With this system, since the external means sets the unit price of the source, it is possible for the source provider to update and alter the unit price with ease.

As still further preferable feature, the unit price in the unit price setting area may be set and updated from a provider of the source via a communication line.

With this system, since the source provider sets and updates the unit price via the communication line, it is possible for the source provider to update and change the unit price with ease.

As an additional preferable feature, the system for automatically collecting charges may comprise a monitor for displaying at least one of the source consumptions, the charges in accordance with the source consumptions, and balance of electronic money stored in the respective user's medium. Particularly, the monitor may be a user's monitor for displaying at least one of the source consumption for the user, the charge in accordance with the source consumption for the user, and balance of electronic money stored in the user's medium of the corresponding user, for the user.

With this system, since the user saves on the resource and loads electronic money in user's medium before the electronic money remained in the user's medium runs short with reference to the information on the user's monitor, it is possible to improve the service to the user.

Alternatively the monitor may be a charge collector's monitor for displaying at least one of the source consumptions for the individual users, the charges in accordance with the individual source consumptions, and balance of electronic money stored in the respective user's mediums, on the charge collector side.

With this system, since the resource provider obtains the information about tendency of the use of the resource and keeps the system for automatically collecting charges in good condition with reference to the information on the charge collector's monitor, it is possible for the resource provider to improve the service to the user with ease.

As still further preferable feature, the system for automatically collecting charges may further comprise a payment medium for storing the electronic money, which has been collected from the user's mediums by the charge collector, or may further comprise a collector's payment unit for receiving the electronic money, which has been stored in the payment medium.

With this system, it is possible to receive the charge in accordance with the source consumption, which charge is collected form the user's medium, with ease.

As still further preferable feature, the collector's payment unit may send the electronic money, which has been received from the payment medium, to a provider of the source via a communication line. As still further preferable feature, a system for automatically collecting charges may further comprise a mobile terminal includes a memory for receiving the electronic money, which the collector's payment unit has been received from the payment medium, from the collector's payment unit and for storing the received electronic money.

The system for automatically collecting charges having above-mentioned generic and preferable features collects the charge in accordance with source consumptions from the user's mediums as equivalent amounts of electronic money at any time as required.

Other objects and further features of the present invention will be apparent from the following detailed description when read in conjunction with the accompanying drawings.

### BRIEF DESCRIPTION OF THE DRAWINGS

FIG. 1 is a block diagram schematically showing an automatic charge collection system according to a first embodiment of the present invention;

FIG. 2 is a block diagram schematically showing an example of the automatic charge collection system of FIG. 1 in use;

FIG. 3 is a diagram showing various history records created in the automatic charge collection system of FIG. 1;

FIG. 4 is a diagram showing state of storing electronic money in an IC card in the automatic charge collection system of FIG. 1;

FIG. 5 is a diagram showing a user's payment history record stored in the IC card in the automatic charge collection system of FIG. 1;

FIG. 6 is a diagram showing a function of a centralized terminal in the automatic charge collection system of FIG. 1;

FIG. 7 is a diagram showing an example of an operational information table in the automatic charge collection system of FIG. 1;

FIG. 8 is a diagram showing an example of a source transaction history record stored in the centralized terminal in the automatic charge collection system of FIG. 1;

FIG. 9 is a diagram showing an example of a saving history record stored in another IC card in the automatic charge collection system of FIG. 1;

FIG. 10 is a diagram showing an example of a receipt history record stored in the other IC card in the automatic charge collection system of FIG. 1 ;

FIG. 11 is a diagram showing an example of a payment transaction history record stored in a collector's payment unit in the automatic charge collection system of FIG. 1;

FIGS. 12(a) through 12(g) are diagrams respectively showing examples of telegrams issued from various elements of the automatic charge collection system of FIG. 1;

FIG. 13 is a diagram showing a process of collecting a charge in accordance with an amount of a source consumed by a user from the IC card at any time as required in the automatic charge collection system of FIG. 1;

FIG. 14 is a diagram showing a process of receiving electronic money stored in the other IC card performed by a source providing company (source provider) in the automatic charge collection system of FIG. 1;

FIG. 15 is a diagram showing a process of stopping providing a source when a charge is not collected from the IC card for some reason in the automatic charge collection system of FIG. 1;

FIG. 16 is a diagram showing a process of recommencing providing a source which has been stopped in the automatic charge collection system of FIG. 1; and

FIG. 17 is a diagram showing a process of updating the operational information table performed by the source provider in the automatic charge collection system of FIG. 1.

### DESCRIPTION OF THE PREFERRED EMBODIMENTS

A preferred embodiment of the present invention will now be described with reference to the accompanying drawings.

(A) First Embodiment:

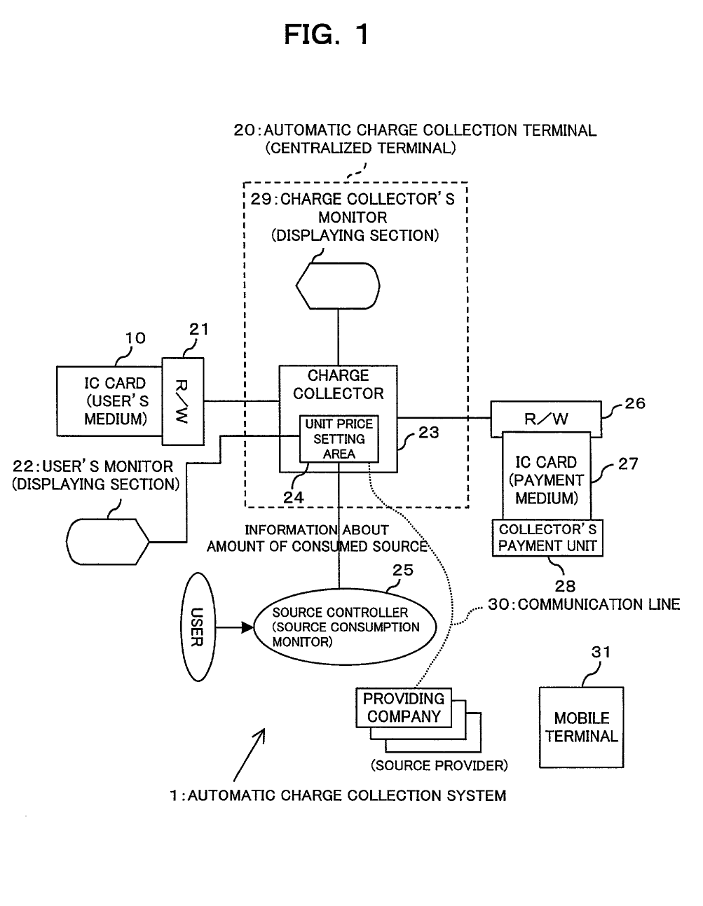

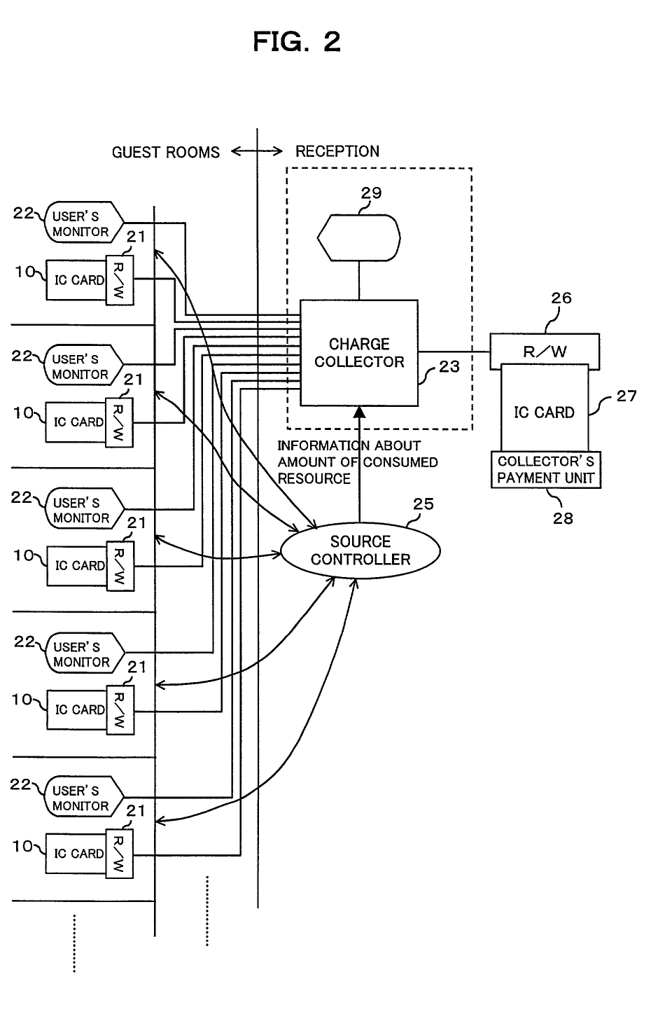

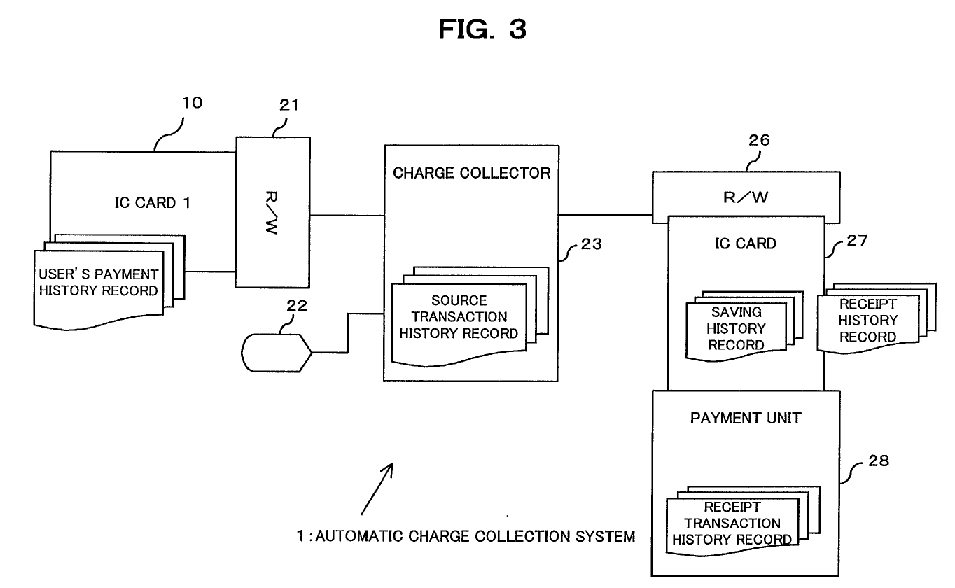

FIG. 1 is a block diagram schematically showing an automatic charge collection system according to a first embodiment of the present invention; FIG. 2 is a block diagram schematically showing an example of the automatic charge collection system of FIG. 1 in use; and FIG. 3 is a diagram showing various history records created in the automatic charge collection system of FIG. 1.

The automatic charge collection system 1 of the illustrated embodiment automatically collects a charge in accordance with source consumption, such as water or electricity. The automatic charge collection system 1 comprises an automatic charge collection terminal (hereinafter also called centralized terminal) 20, an IC card (user's medium) 10, an IC card reader/write (hereinafter called R W) 21, and a user's monitor (display section) 22, as shown in FIG. 1.

When the system 1 is applied to a hotel or a weekly rental condominium to collect a charge in accordance with a source (e.g., water, electricity, television) consumed by a guest, the centralized terminal 20 is installed in a reception and the R Ws 21 are in each guest room, as shown in FIG. 2. A guest (user) inserts the IC card 10 in which electronic money is stored into the R W 21, which is installed in each guest room, so that a charge in accordance with the source consumption is collected from the IC card 10 as a corresponding equivalent amount of electronic money.

The IC card (user's medium) 10 is provided for the user and stores electronic money, which is defined as an electronic alternative to a currency. The electronic money stored in the IC card 10 is rewritable.

The IC card 10 comprises an MPU (Micro Processor Unit), a ROM, a RAM, a data memory, and a connecting section, which are not illustrated in the accompanying drawings. One or more programs for driving the MPU and a non-illustrated arithmetic unit are installed in the ROM.

The MPU and the arithmetic unit operate in accordance with the programs installed in the ROM. As a result, the IC card 10 functions by temporarily storing deposit and withdrawal data regarding electronic money, which data is input from a non-illustrated external apparatus, and arithmetic data of a result of arithmetic operation in the arithmetic unit based on the deposit and withdrawal data in the RAM. Further, the IC card 10 functions by passing the deposit and withdrawal data and the arithmetic data to the data memory and passing the data to an external apparatus via the connecting section.

The data memory stores information about an amount (balance) of the electronic money, as the result of an arithmetic operation performed in the MPU or other operations, and consists of a PROM (programmable ROM). Namely, the data memory is operable to store electronic money.

The connecting section is in the form of an electrode connected to an external unit, such as the IC card reader/writer (R W) 21 connected to the centralized terminal 20 in FIG. 1. The IC card 10 sends and receives the deposit and withdrawal data or the like with the external unit via the connecting section.

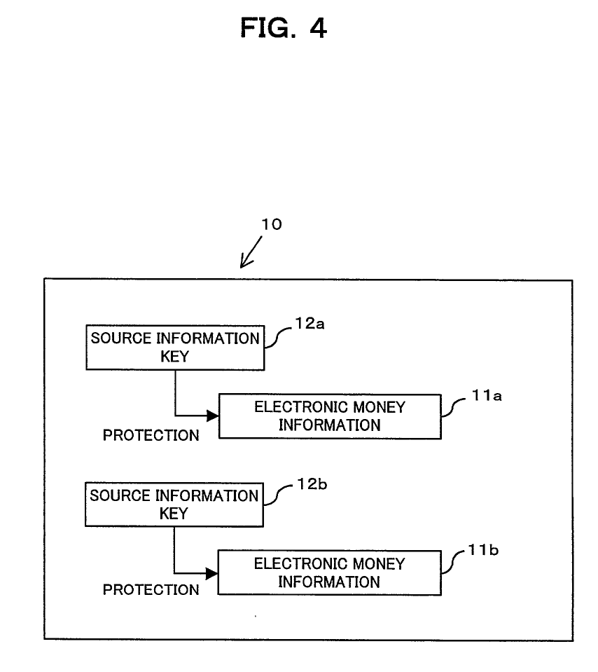

FIG. 4 is a diagram showing state of storing electronic money in an IC card used in the automatic charge collection system 1. As shown in FIG. 4, a plurality (two in FIG. 4) of pieces of electronic money information 11a, 11b are stored in the data memory of the IC card 10. The electronic money information 11a, 11b are information about electronic money, and include amount of electronic money and kind of a currency (e.g., yen, dollar). The each electronic money information 11a, 11b are respectively dedicated to individual sources (purposes), such as water or electricity.

The electronic money information 11a, 11b are respectively protected by source information key 12a, 12b so that an unauthorized person cannot use electronic money in the IC card 10.

An example of the manner that a user loads the IC card 10 with electronic money will now be described. First of all, a user inserts the IC card 10 in an ATM (Automated Tellers Machine) compliant with electronic money in a banking agent to request for issue of electronic money via the ATM. Responsive to the request, the host computer of the banking agent subtracts a requested amount of money from an account of the user, issues the corresponding equivalent amount of electronic money, and stores the issued electronic money in the data memory of the IC card 10 through the ATM. It is also possible to encash electronic money and deposit money in an account using electronic money in the same manner as issuing electronic money using an ATM.

It is possible for the user to pay for a water charge or an electricity charge in the form of a corresponding equivalent amount of electronic money stored in the IC card 10 by inserting the IC card 10, which is carried as a substitution for a purse by the user, in the R W 21.

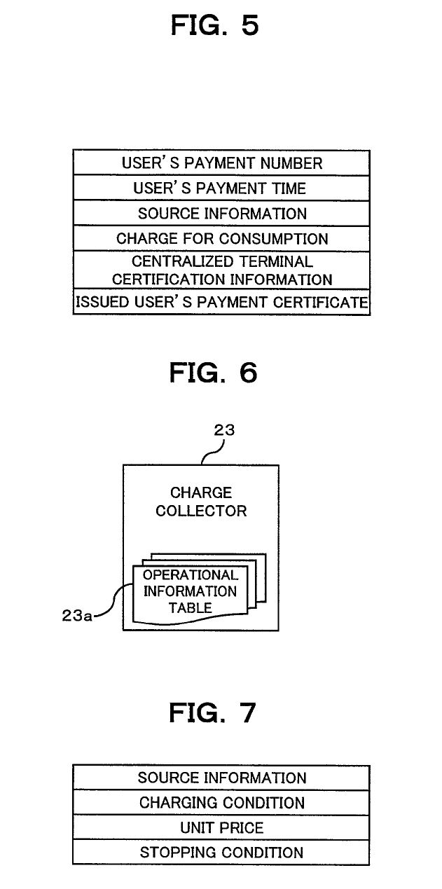

The IC card 10 retains history records of user's payment performed by the user using the electronic money in the electronic money information 11a, 11b regarding individual resources. FIG. 5 is a diagram showing a user's payment history record stored in the IC card 10 in the automatic charge collection system 1. The IC card 10 retains the user's payment history record including a user's payment number, user's payment time, source information, a charge for consumption, centralized terminal certification information, and an issued user's payment certificate, as shown in FIG. 5.

The “user's payment number” identifies each user's payment and is set by the centralized terminal 20; the “user's payment time” identifies date and time when the user's payment is performed; the “source information” identifies a source (e.g., water or electricity) of which the user's payment is performed for the consumption; the “charge for consumption” is an amount of paid electronic money and is calculated by a charge collector 23 in the manner described later; the “issued user's payment certificate” certifies the user's payment using the electronic money and is issued from the centralized terminal 20; and the “centralized terminal certification information” is used for certification of the user's payment.

The IC card reader/writer (R W) 21 is inserted the IC card 10, and reads/updates data (an amount) of electronic money stored in the data memory of the IC card 10. Further, the R W 21 is controlled by the centralized terminal 20 (the charge collector 23) as describe later.

The user's monitor 22 is in the form of a display, an LCD (liquid crystal display), a touch panel or the like and a plurality of the user's monitors 22 are, as shown in FIG.2, installed in individual guest rooms together with the R Ws 21. The user's monitor 22 is communicably connected with the centralized terminal 20.

The user's monitor 22 is further controlled by the centralized terminal 20 and displays for the user the source consumption, a charge in accordance with the source consumption, and balance of electronic money stored in the IC card 10.

Namely, the user can confirm the source consumption measured by a source controller 25, the charge in accordance with the source consumption, the balance of electronic money stored in the IC card 10 by looking at the user's monitor 22.

The centralized terminal (automatic charge collection terminal) 20 automatically collects the charge in accordance with the source consumption, such as water or electricity. The centralized terminal 20, as shown in FIG. 1, includes the charge collector 23 and a charge collector's monitor (displaying section) 29, and is connected with the source controller (source consumption monitor) 25 and an IC card reader/writer (R W) 26.

The centralized terminal 20 is in the form of a general personal computer, and therefore the CPU and the display of the personal computer function as the charge collector 23 and the collector's monitor 29.

The source controller (source consumption monitor) 25 monitors the source consumption, and is, for example, equipped with a meter of the like. The source controller 25 monitors an amount of the individual sources consumed by the user and sends the centralized terminal 20 the result of the monitoring as information about amount of consumed source. The source controller 25 is controlled by the centralized terminal 20 (the charge collector 23) and can stop providing the user with the source based on the control of the charge collector 23.

The charge collector 23 collects the charge in accordance with the source consumption, which is monitored by the source controller 25, from the IC card 10 as corresponding equivalent amount of electronic money. The charge collector 23 collects the charge in accordance with the source consumption monitored by the source control section 25 from the user's medium at any time as required.

When the charge in accordance with the source consumption is not collected from the IC card 10, the charge collector 23 stops providing the user with the source by controlling the source controller 25.

Further, the charge collector 23 includes a unit price setting area 24, in which the unit prices of the individual sources are set from an external unit, program, or etc. of the charge controller 23. A source provider (a providing company) previously sets the unit prices of the individual sources.

FIG. 6 is a diagram showing a function of the charge collector 23 in the automatic charge collection system 1; and FIG. 7 is a diagram showing an example of an operational information table 23a in the automatic charge collection system 1. The charge collector 23, as shown in FIG. 6, has the operational information table 23a, which includes source information, a charging condition, a unit price, and a stopping condition with respect to individual sources, as shown in FIG. 7.

The operational information table 23a is in a non-illustrated storage area in the centralized terminal 20, and the storage area functions as the unit price setting area 24.

The “source information” identifies a kind of a source (e.g., water, electricity, television). The “charging condition” is a condition (a unit) for charging for the source. If the source is water and the charge for the source is charged every time when a litter of water is consumed, “1 litter” is registered as the “charging condition”. And if the source is television and the charge for the source is charged every time when a television is turned on for 30 minutes in total, “30 minutes” is registered as the “charging condition”.

The “unit price” is a unit price of the source to be provided the user and is a unit price per the individual “charging condition”. The “stop condition” is a condition for stopping providing the source by the source controller 25. If “delinquency: three times” is registered as the “stop condition” and the user fails to pay for a charge three or more times, providing the user with the source is stopped.

The charge collector 23 calculates a charge for the source consumption based on the amount of the source consumption monitored by the source controller 25 and the unit price set in the unit price setting area 24, and whereupon the calculated charge is collected from the IC card 10.

The charge collector 23 (the centralized terminal 20) is communicably connected with the providing company, which is the source provider, via a communication line 30, as described later. The source provider sets and updates the unit price stored in the unit price setting area 24 via the communication line 30. Alternatively, it is also possible to set and update the unit price using a non-illustrated inputting device, such as a keyboard, equipped with the centralized terminal 20.

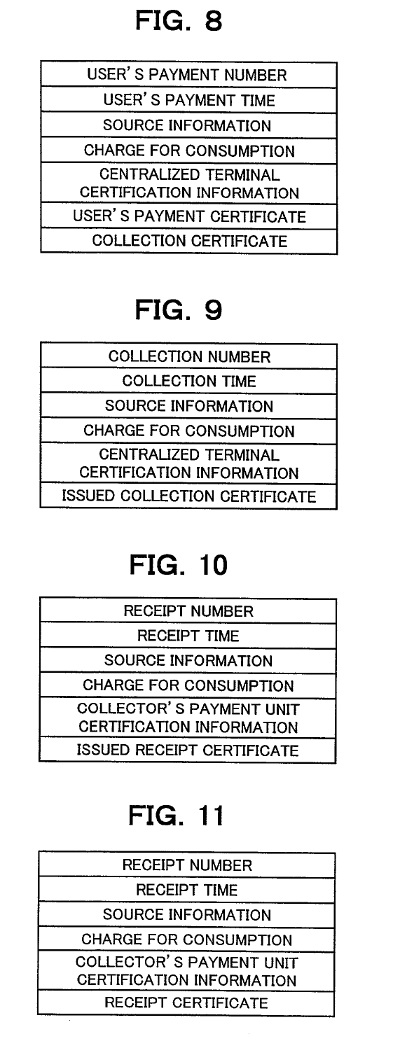

The charge collector 23 maintains history records as source transaction history records, as shown in FIG. 8, each time when the charge collector 23 collects the charge in accordance with the source consumption from the IC card 10 as corresponding equivalent amount of electronic money. FIG. 8 is a diagram showing an example of the source transaction history record stored in the charge collector 23 in the automatic charge collection system 1. The charge collector 23 maintains the source transaction history record containing a user's payment number, user's payment time, source information, a charge for consumption, centralized terminal certification information, a user's payment certificate, and a collection certificate, as shown in FIG. 8.

The “user's payment number” identifies each user's payment and is set by the charge collector 23; the “user's payment time” identifies date and time when the user's payment is performed; the “source information” identifies a source (e.g., water or electricity) of which the user's payment is performed for the consumption; the “charge for use” is a value of electronic money paid from the IC card 10 and is calculated by an charge collector 23; the “user's payment certificate” certificates the user's payment for the charge from the IC card 10 in the form of electronic money; the “collection certificate” certificates that the centralized terminal 20 collects (stores) the electronic money, which is paid from the IC card 10, in another IC card 27 (payment medium) via a R W 26; and the “centralized terminal certification information” is used for the user's payment certification and for the collection certification.

The centralized terminal 20 respectively controls the R Ws 21, 26, the user's monitor 22, and the charge collector's monitor 29.

The centralized terminal 20, for example, controls the R W 21 so that the calculated charge in accordance with the source consumption is collected from the IC card 10 as corresponding equivalent amount of electronic money, and also updates the user's payment history record shown in FIG. 5.

The centralized terminal 20 further controls the R W 26 so that the electronic money collected from the IC card 10 as the charge for the source consumption is stored (saved) in the IC card 27. And the centralized terminal 20 stores the history of this saving as the saving history record (FIG. 3) in the IC card 27.

The IC card 27 stores electronic money, which is defined as an electronic alternative to a currency, likewise the IC card 10. The electronic money in also the IC card 27 is rewritable. The IC card 27 is identical in construction with the IC card 10, so further description is omitted here.

The IC card 27 is communicably connected with the R W 26 and a collector's payment unit (charge collector's payment unit) 28, respectively. The R W 26 stores electronic money in a data memory of the IC card 27, and the collector's payment unit 28 receives the electronic money stored in the data memory of the IC card 27.

Further, the IC card 27 is detachably connected with the R/W 26 and the collector's payment unit 28, respectively.

The electronic money stored in the IC card 27 is received by (paid to) the collector's payment unit 28, and the electronic money, as the payment for the charge for the source consumption, is paid to the providing company (the source provider) from the payment unit 28 via a communication line 30 or a mobile terminal 31, which are described later.

The IC card 27 maintains history records of saving electronic money collected by the charge collector 23 and a history record of receiving electronic money by the collector's payment unit 28. FIG. 9 is a diagram showing an example of the saving history record stored in the IC card 27 in the automatic charge collection system 1; and FIG. 10 is a diagram showing an example of a receipt history record stored in the IC card 27.

The IC card 27 maintains a saving history record, as shown in FIG. 9, including a collection number, collection time, source information, a charge for consumption, centralized terminal certification information, and an issued collection certificate.

The “collection number” identifies each collection process of electronic money and is set by the charge collector 23; the “collection time” identifies date and time when the collection of electronic money is performed; the “source information” identifies a source (e.g., water or electricity) of which the collected electronic money is paid from the IC card 10 for the consumption; the “charge for consumption” is an amount of collected electronic money; the “issued collection certificate” certificates the collection of electronic money performed by the charge collector 23 and is issued from the centralized terminal 20; and the “centralized terminal certification information” is used for certification of the collection.

The IC card 27 also maintains a receipt history recode, as shown in FIG. 10, includes a receipt number, receipt time, source information, a charge for consumption, collector's payment unit certification information, and an issued receipt certificate.

The “receipt number” identifies each receipt of electronic money from the IC card 27 performed by the collector's payment unit 28 and is set by the collector's payment unit 28; the “receipt time” identifies date and time when the collector's payment unit 28 receives electronic money from the IC card 27; and the “issued receipt certificate” is used for certification of the receipt of electronic money by the collector's payment unit 28 and is issued from the collector's payment unit 28.

The charge collector's monitor 29 is in the form of a display, an LCD, a touch panel or the like, same as the user's monitor 22. The charge collector's display 29 displays the source consumption, a charge in accordance with the source consumption, and the balance of electronic money stored in the IC card 10 in the centralized terminal 20. Also the charge collector's monitor 29 is controlled by the centralized terminal 20.

As a result, the source provider confirms the source consumption measured by the source controller 25, a charge in accordance with the source consumption, and the balance of electronic money stored in the IC card 10 by looking at the charge collector's monitor 29.

The collector's payment unit 28 receives electronic money stored in the IC card 27, and includes a non-illustrated memory area for temporarily storing the electronic money. The collector's payment unit 28 further passes (pays) the temporarily stored electronic money to the source provider via the communication line 30 or the mobile terminal 31. The collector's payment unit 28 maintains the receipt history record, as shown in FIG. 10, in the IC card 27.

The collector's payment unit 28 also maintains a history record of receipt of electronic money from the IC card 27 as a receipt transaction history record. FIG. 11 is a diagram showing an example of the receipt transaction history record stored in a collector's payment unit 28 in the automatic charge collection system 1. The collector's payment unit 28 maintains the receipt transaction history record, as shown in FIG. 11, including a receipt number, receipt time, source information, a charge for consumption, collector's payment unit 28 certification information, and a receipt certificate.

The “receipt number” identifies each receipt of electronic money of the collector's payment unit 28 and is set by the collector's payment unit 28; the “receipt time” identifies date and time when the receipt is performed; the “source information” identifies a source (e.g., water or electricity) of which the received electronic money is paid from the IC card 10 for the source consumption; the “charge for consumption” is an amount of received electronic money; the “issued receipt certificate” certifies the receipt of the electronic money as the charge for the source consumption and is issued from the centralized terminal 20; and the “receipt certification information” is used for certification of the receipt.

The communication line 30 communicably connects the centralized terminal 20 with the source provider and is exemplified by the Internet. The source provider changes and updates the contents (e.g., the charging condition, the unit price, the stopping condition) in the operational information table 23a of the charge collector 23 via the communication line 30.

The source provider instructs the collector's payment unit 28, via the communication line 30 to receive the electronic money stored in the IC card 27. The source provider also receives, via the communication line 30, the electronic money paid from the collector's payment unit 28, which has received the electronic money from the IC card 27, and deposits, via the communication line 30, the paid electronic money in a banking account.

The mobile terminal 31 has a memory for receiving electronic money, which the collector's payment unit 28 has received from the IC card 10, paid from the payment unit 28 and is exemplified by a handy terminal.

Alternatively, the source provider may directly receive electronic money stored in the IC card 27 by demounting the IC card 27 from the collector's payment unit 28 and then inserting the IC card 27 in the mobile terminal 31 to transfer the electronic money to the memory in the mobile terminal 31.

Further, the source provider may receive electronic money by connecting the mobile terminal 31 with the collector's payment unit 28 using a communication cable or etc. to transfer electronic money stored in the memory area of the collector's payment unit 28 to the memory in the mobile terminal 31.

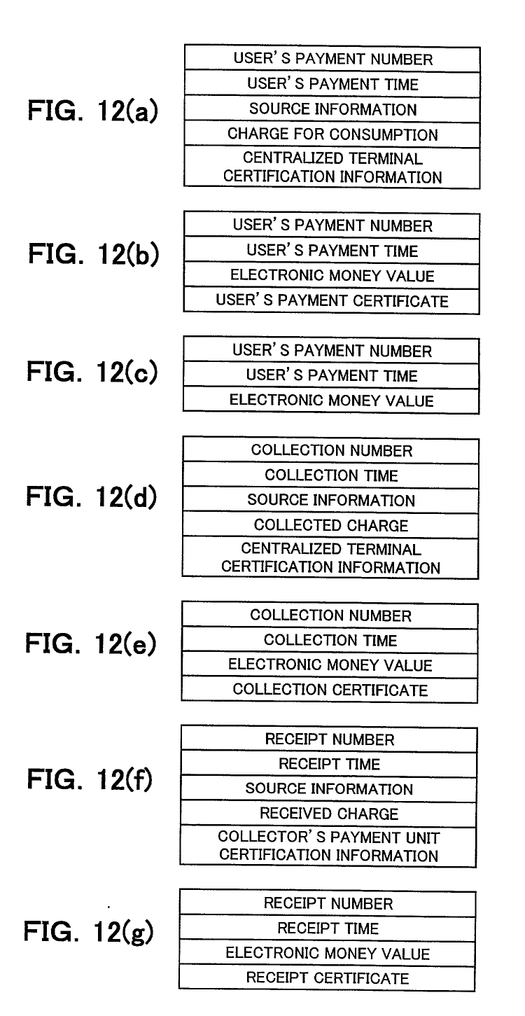

Various processes performed in the automatic charge collection system 1 having above-described elements and functions will now be described with reference to accompanying drawings as follows: (1) user's payment using the IC card 10; (2) receipt of paid electronic money of the providing company; (3) stopping providing the source due to a balance shortage; (4) recommencement of providing the supply-stopped source; and (5) update of operational information by the providing company. FIGS. 12(a) through 12(g) are diagrams respectively showing examples of telegrams issued from various elements in the automatic charge collection system 1.

(1) User's payment using the IC card 10:

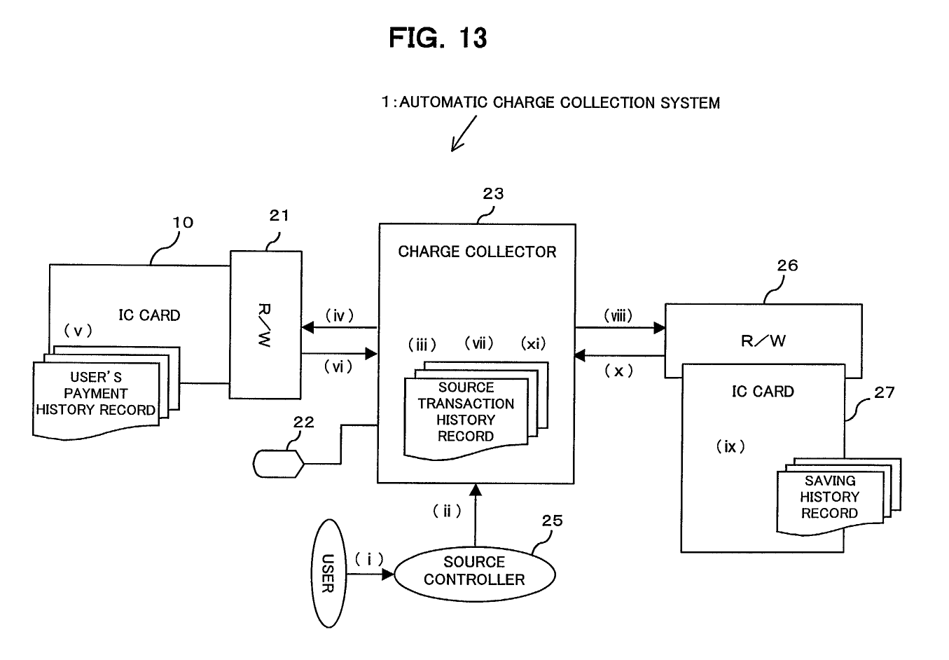

FIG. 13 is a diagram showing a process of collecting a charge in accordance with an amount of the source consumed by a user from the IC card 10 at any time as required in the automatic charge collection system 1. The charge collecting process is carried out in the order of procedures (i) through (xi) in FIG. 13.

As shown in FIG. 13, when the user consumes a source (procedure (i)), the source controller 25 monitors the amount of the source consumption and sends the amount as information about amount of consumed source to the charge collector 23 at any time as required (in real time) (procedure (ii)).

If the amount of the resource consumption accompanies a charge for the source consumption, the charge collector 23 creates the source transaction history record (FIG. 8), stores it in the storage area thereof, and starts the collection of the charge (procedure (iii)).

The charge collector 23 calculates the charge to be collected for the source consumption based on information previously registered in the operational information table 23a (FIG. 7), time, and the amount of the consumed source, which amount is sent from the source controller 25. At the same time, the charge collector 23 creates a user payment instruction telegram and sends the telegram to the IC card 10 (procedure (iv)).

FIG. 12(a) is an example of the user payment instruction telegram, which is sent to the IC card 10 from the charge collector 23. The user payment instruction telegram includes a user's payment number, user's payment time, source information, a charge for consumption, and centralized terminal certification information, as shown in FIG. 12(a).

The “collected number” identifies each user payment instruction and is set by the charge collector 23; the “user's payment time” is date and time when the user payment instruction is sent to the IC card 10; the “source information” identifies a source (e.g., water or electricity) of which the electronic money to be collected is paid for a charge in accordance with the consumption; the “charge for consumption” is a charge for the source consumption and is calculated by the charge collector 23; and the “centralized terminal certification information” is used for certification of the user's payment request.

Upon receipt of the user payment instruction, the IC card 10 makes a user's payment of the charge for the source consumption as an corresponding equivalent amount of electronic money based on the user payment instruction telegram, and stores the user's payment history record (FIG. 5) (procedure (v)). The IC card 10 further sends the charge collector 23 a user payment response telegram (procedure (vi)).

FIG. 12(b) is an example of the user payment response telegram, which is sent to the charge collector 23 from the IC card 10. The user payment response telegram includes a user's payment number, user's payment time, electronic money value (a charge for consumption), and a user's payment certificate, as shown in FIG. 12(b).

The “use's payment number” identifies each user's payment and is set by the charge collector 23; the “user's payment time” identifies date and time when the user's payment is performed; the “electronic money value” is an amount of electronic money paid from the IC card 10; and the “user's payment certificate” certifies that the IC card 10 made the user's payment.

The charge collector 23 updates the source transaction history record (FIG. 8) (procedure (vii)), and creates a collected charge saving telegram used for storing (saving) the charge for the source consumption collected from the IC card 10 in the form of electronic money in the IC card 27, based on the amount of the collected electronic money and the source information keys 12a, 12b (FIG. 4). Then the collected charge saving telegram is sent to the R W 26 (procedure (viii)).

FIG. 12(d) is an example of the collected charge saving telegram, which is sent to the R W 26 from the charge collector 23. The collected charge saving telegram includes a collection number, collection time, source information, a collected charge, and centralized terminal certification information, as shown in FIG. 12(d).

The “collection number” identifies each collection of electronic money and is set by the charge collector 23; the “collection time” identifies date and time when an instruction of saving the electronic money is sent to the R W 26; the “source information” identifies a source of which the electronic money to be saved is the charge for consumption; and the “collected charge” is an amount of the collected electronic money; and the “centralized terminal certification information” is used for certification as the saving instruction is sent to the R W 26.

The R W 26 saves the charge collected by the charge collector 23 in the form of electronic money in the data memory of the IC card 27 with respect to individual source, and maintains the saving history record (FIG. 9) in the IC card 27 (procedure (ix)).

The IC card 27 sends the automatic charge collection terminal 20 (the charge collector 23) a charge collection response telegram (procedure (x)), which is collection certificate. FIG. 12(e) is an example of the charge collection response telegram, which is sent to the charge collector 23 from the R W 26. The charge collection response telegram includes a collection number, collection time, electronic money value (a collected charge) and a collection certificate, as shown in FIG. 12(e)

The “collection number” identifies each collection and is set by the charge collector 23; the “collection time” identifies date and time when the collected electronic money is saved; the “electronic money value” is an amount of the collected electronic money; and the “collection certificate” certificates that the R W 26 saves the collected electronic money in the data memory of the IC card 27.

In the meantime, the charge collector 23 updates the source transaction history record (FIG. 8) based on the received charge collection response telegram (procedure (xi)).

(2) Receipt of paid electronic money of the providing company:

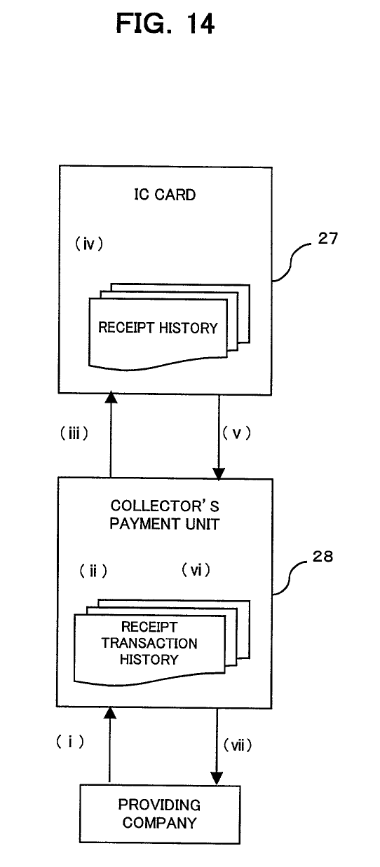

FIG. 14 is a diagram showing a process of receiving electronic money stored in the IC card 27 by the providing company (the source provider) in the automatic charge collection system 1. The receipt process is carried out in the order of procedures (i) through (vii) in FIG. 14.

When the providing company instructs the collector's payment unit 28 via the communication line 30 to receive the charge in accordance with the source consumption (procedure (i)), the collector's payment unit 28 creates the receipt transaction history record (FIG. 11) (procedure

Subsequently, the collector's payment unit 28 sends a saved charge payment instruction telegram to the IC card 27 (procedure (iii)). FIG. 12(f) is an example of the saved charge payment instruction telegram, which is sent to the IC card 27 from the collector's payment unit 28. The saved charge payment instruction telegram includes a receipt number, receipt time, source information, received charge, and collector's payment unit certification information, as shown in FIG. 12(f).

The “receipt number” identifies each instruction that the collector's payment unit 28 receives electronic money from the IC card 27 and is set by the collector's payment unit 28; the “receipt time” identified date and time when the instruction of receiving electronic money is issued to the IC card 27; the “source information” identifies a source (e.g., water or electricity) of which the collected electronic money is paid from the IC card 10 for the consumption; the “gathered charge” is an amount of electronic money to be received by collector's payment unit 28, and all amount of electronic money stored in the IC card 27 may be automatically received in the collector's payment unit 28 or a providing company may assign an amount of electronic money to be received in the collector's payment unit 28; and the “payment unit certification information” is used when a request for the receipt of electronic money is issued to the collector's payment unit 28.

The IC card 27 sends electronic money stored therein with respect to individual source to the collector's payment unit 28 based on the received saved charge payment instruction telegram, in which the amount to be paid to the collector's unit 28 is assigned, and, at the same time, updates the receipt history record (FIG. 10) (procedure (iv)).

Further, the IC card 27 sends the collector's payment unit 28 a saved charge receipt response telegram based on the amount of the electronic money paid to the collector's payment unit 28 (procedure (v)).

FIG. 12(g) is an example of the saved charge receipt response telegram, which is sent to the collector's payment unit 28 from the IC card 27. The saved charge receipt response telegram includes a receipt number, receipt time, an electronic money value, and a receipt certificate, as shown in FIG. 12(g).

The “receipt number” identifies each receipt of electronic money in the collector's payment unit 28 and is set by the collector's payment unit 28; the “receipt time” is date and time when the collector's payment unit 28 receives the electronic money from the IC card 27; the “electronic money value” is an amount of the received electronic money; and the “receipt certificate” certificates that the collector's payment unit 28 receives the electronic money from the IC card 27.

The collector's payment unit 28 updates the receipt transaction history record (FIG. 11) based on the received saved charge payment response telegram (procedure (vi)). Subsequently, the collector's payment unit 28 provides the provided company with the received electronic money (information about a paid charge) (procedure (vii)). Alternatively, the collector's payment unit 28 may directly deposit the received electronic money in a banking account of the providing company or the like.

(3) Stopping providing the source due to a balance shortage:

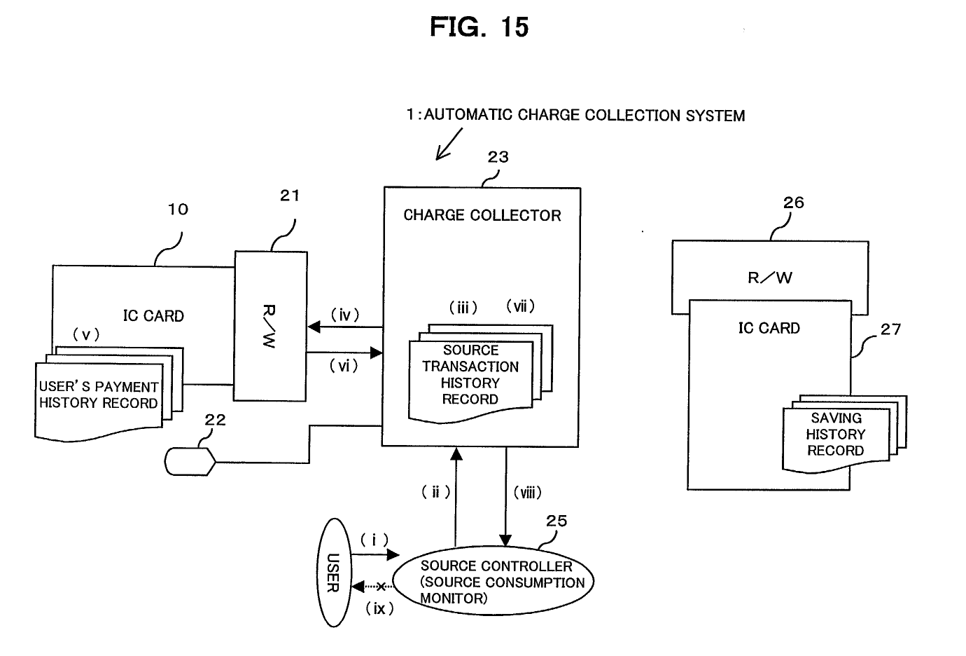

FIG. 15 is a diagram showing a process of stopping providing the user with the source when a charge is not collected from the IC card 10 for some reason in the automatic charge collection system 1. The stopping process is carried out in the order of procedures (i) through (ix) in FIG. 15.

When a user consumes the source (procedure (i)), the source controller 25 monitors the amount of the source consumed by the user and sends the amount as information about the amount of consumed source to the charge collector 23 at any time as required (in real time) (procedure (ii)).

If the amount of the consumed source accompanies a charge for the source consumption, the charge collector 23 creates the source transaction history record (FIG. 8) to store it in the storage area thereof and starts the collection of the charge (procedure (iii)).

The charge collector 23 calculates the charge to be collected based on information previously registered in the operational information table 23a (FIG. 7), time, and the amount of the consumed source, which amount is sent from the source controller 25. At the same time, the charge collector 23 creates a user payment instruction telegram and sends the telegram to the IC card 10 (procedure (iv)).

The IC card 10, to which a user payment instruction telegram is sent, makes the user's payment of the charge for the source consumption by drawing a corresponding equivalent amount of electronic money stored therein based on the user payment instruction telegram, and records the user's payment history record (FIG. 5) (procedure (v)).

At that time, since the amount of the electronic money in the IC card 10 is insufficient, the IC card 10 sends the charge collector 23 a user payment denial response telegram (procedure (vi)).

FIG. 12(c) is an example of the user payment denial response telegram, which is sent to the charge collector 23 from the IC card 10. The user payment denial response telegram includes a user's payment number, user's payment time, and an electronic money value (charge for source consumption), as shown in FIG. 12(c).

The “user's payment number” identifies each user's payment is set by the charge collector 23; the “user's payment time” identifies date and time when the charge collector 23 requests the user's payment; and the “electronic money value” is an amount of electronic money to be paid from the IC card 10.

The charge collector 23 updates the source transaction history record (FIG. 8) (procedure (vii)). Further, the charge collector 23 refers to a stopping condition in the operational table 23a (FIG. 7) and, if the state of the current transaction is in the stop condition, the charge collector 23 sends service stopping information (service providing stopping instruction) to the source controller 25. After that, the charge collector 23 waits for a deposit of electronic money in the IC card 10 (procedure (viii)).

The source controller 25 stops providing the service (source) responsive to the instruction from the charge collector 23 (procedure (ix)).

(4) Recommencement of providing the supply-stopped source:

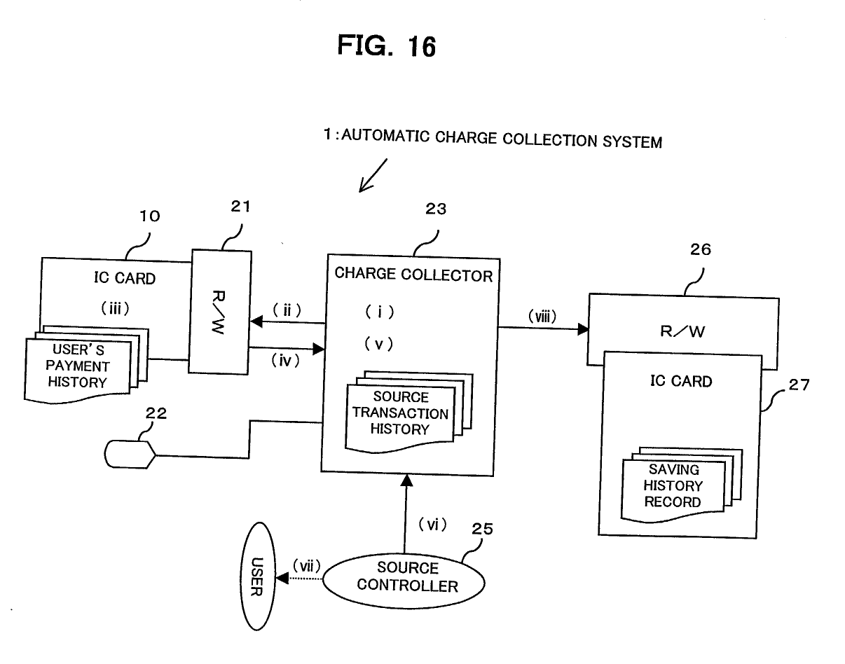

FIG. 16 is a diagram showing a process of recommencement of providing the supply-stopped source in the automatic charge collection system 1. The recommencement process is carried out in the order of procedures (i) through (viii) in FIG. 16.

The charge collector 23 waits for a deposit of electronic money in the IC card 10 (procedure (i)). When the IC card 10, in which electronic money is loaded, is inserted into the R W 21, the charge collector 23 creates the user payment instruction telegram (FIG. 12(a)) based on the calculated charge for the source consumption, and sends the telegram to the IC card 10 (procedure (ii)).

The IC card 10 makes a payment for the charge for the source in the form of electronic money base on the user payment instruction telegram received from the charge collector 23 and updates the user's payment history record (FIG. 5) (iii), which is created in the above-mentioned process of “(3) Stopping providing the source due to a balance shortage”. The IC card 10 also sends the automatic charge collection terminal 20 the user payment response telegram (FIG. 12(b)) in accordance with the amount of paid electronic money (procedure (iv)).

The charge collector 23 updates the source transaction history record (FIG. 8) (procedure (v)), which is created in the above-mentioned process in “(3) Stopping providing the source due to balance shortage”. Further, when the charge collector 23 successfully collects the charge for the source consumption from the IC card 10, the charge collector 23 sends the source controller 25 service starting information in the form of a telegram for recommencement of providing the source (procedure (vi)).

Upon receipt of the service stating information, the source controller 25 recommences providing the source (procedure (vii)). At that time, the charge collector 23 restarts the process as mentioned in “(1) user's payment using the IC card 10” (procedure (viii)).

(5) Update of operational information performed by the providing company:

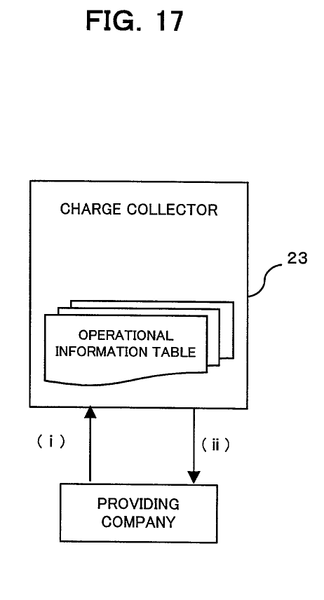

FIG. 17 is a diagram showing a process of updating the operational table 23a in the charge collector 23 performed by the source provider. The updating process is carried out in the order of procedures from (i) to (ii) in FIG. 17.

The source provider (the providing company) creates another operational information table, and sends it to the charge collector 23 via the communication line 30 or the like (procedure (i)). The charge collector 23 updates the operational information table 23a, which is stored in the storage area thereof, by using the other operational information table, which is received from the source provider (procedure (ii)).

Since the charge in accordance with the source consumption is collected from the IC card 10 as a corresponding equivalent amount of electronic money in the automatic charge collection system 1, it is possible for the source provider to surely collect the charge for the source consumption.

If the user moves to another place or leave a hotel, it is possible to reduce the labor of both the user and the service provider since it does not necessitate various procedures, such as stopping and starting providing the service, setting a manner of user's payment for the charge.

It is possible to collect the charge for the source (e.g., water or electricity) consumed by a guest with a reduced amount of labor especially in a hotel, a weekly rental condominium, or etc.

Since the centralized terminal (automatic charge collection terminal) 20 (the charge collector 23) collects the charge from the IC card 10 in accordance with the source consumption at any time as required, it is possible for the source provider to surely collect the charge.

Further, if the charge of the source consumption is unsuccessfully collected from the IC card 10 due to a balance shortage or other reasons, it is possible for the source provider to avoid damages caused from the unsuccessful user's payment since the source controller 25 stops providing the user with the source. More particularly, if sufficient amount of electronic money is not remained in the IC card 10 and the user cannot make the payment for the source consumption, it is possible for the provider to dodge a lot of damages due to the unsuccessful user's payment for the source consumption by stopping providing the source without time delay with reference to the stop condition previously set in the operational information table 23a.

Since an external unit or programs may set the unit price of the source in the operational information table 23a (unit price setting area 24) it is possible for the source provider to change the unit price with a reduced amount of labor.

Since the provider can directly set and change the unit price in the operational information table 23a via the communication line 30, it is also possible to reduce the labor of the provider at that time.

The user confirms at least one of the source consumption, the charge in accordance with the source consumption, and a balance of the electronic money remained in the IC card 10 with ease by looking at the user's monitor 22. As a result, it is possible to improve the service to the user since the user can avoid over-using the source, save on the source consumption, and load electronic money in the IC card before the electronic money stored in the IC card 10 run short.

The charge collector's monitor 29 dedicated to the charge collector 23 displays at lease one of the source consumption, the charge in accordance with the source consumption, and balance of the electronic money stored in the IC card 10, on the centralized terminal 20 side. Therefore it is possible for the source provider to obtain information about the tendency of the source consumption with reference to the information on the charge collector's monitor 29 and to keep the automatic charge collection system 1 in a good condition with ease so that the service to a user is improved.

The collector's payment unit 28 receives electronic money stored in the IC card 27, and then the source provider receives the electronic money from the collector's payment unit 28 via the communication line 30 or the mobile terminal 31 with ease.

(B) Others:

Further, the present invention should by no means be limited to this foregoing embodiment, and various changes or modifications may be suggested without departing from the concept of the invention.

In this embodiment, the payment medium used in the centralized terminal 20 is in the form of the IC card 27. Alternatively, the payment medium may be in the form of a detachable cassette-type data memory or a fixed data memory.

Further, in this embodiments, the user is provided a user's medium of the IC card 10, in which the data memory including a plurality (two in this embodiment) of pieces of electronic money information 11a, 11b in accordance with individual resources. Alternatively, the user may be provided a plurality of the IC cards 10 as many as the kinds of resources. With the plural IC cards 10, a plurality of R Ws 21 may be equipped with each guest room in accordance with the number of the IC cards 10, or the R W 21 may accept the plural IC cards 10 all at once or one at a time.

A plurality of IC cards 27 may be prepared in accordance with the kinds of resources likewise the IC card 10. Further, a plurality of R Ws 26 may be installed in accordance with the number of the IC card 27, or the R W 26 may accept the plural IC cards 27 all at once or one at a time.

Any types of IC card and any kinds of electronic money capable of above-mentioned functions can be used in the present invention.

The communication line 30 should by no means be limited to the Internet, but any communication methods can be also used.

The automatic charge collection system 1 collects the charge in accordance with consumption of water, electricity, or television. Alternatively, the system 1 may also collect the charge in accordance with consumption of beverages stored in a refrigerator equipped with each guest rooms in a hotel, or the charge for other various services. Further, the system 1 should by no means be limited to be used in a hotel or weekly rental condominium. Alternatively, the system 1 may be also used for collecting the charge for utility charges (e.g., electricity, water, gas) used at home.

What is claimed is:

1. A system for automatically collecting charges in accordance with individual consumptions of a source from one or more users, said system comprising:
one or more user's mediums, provided one for each of the users, for storing electronic money, which is defined as an electronic alternative to a currency;
a source consumption monitor for monitoring the source consumptions for the individual users; and
a charge collector for collecting the charges in accordance with the individual source consumptions, which are monitored by said source consumption monitor, from the respective user's mediums as corresponding equivalent amounts of electronic money.

2. A system for automatically collecting charges according to claim 1, wherein said charge collector collects the charges in accordance with the individual source consumptions, which are monitored by said source consumption monitor, from the respective user's mediums at any time as required.

3. A system for automatically collecting charges according to claim 1, wherein, if the charge in accordance with the source consumption is not collected from any one of said user's mediums, said charge collector stops providing the source for the user of said one medium.

4. A system for automatically collecting charges according to claim 2, wherein, if the charge in accordance with the source consumption is not collected from any one of said user's mediums, said charge collector stops providing the source for the user of said one medium.

5. A system for automatically collecting charges according to claim 1, wherein
said source consumption monitor monitors amounts of source consumed by the individual users; and
said charge collector calculates the charges based on the amounts of the consumed source and previously set unit price for the source, and collects the calculated charges from said respective user's mediums.

6. A system for automatically collecting charges according to claim 2, wherein
said source consumption monitor monitors amounts of source consumed by the individual users; and
said charge collector calculates the charges based on the amounts of the consumed source and previously set unit price for the source, and collects the calculated charges from said respective user's mediums.

7. A system for automatically collecting charges according to claim 3, wherein
said source consumption monitor monitors amounts of source consumed by the individual users; and
said charge collector calculates the charges based on the amounts of the consumed source and previously set unit price for the source, and collects the calculated charges from respective user's mediums.

8. A system for automatically collecting charges according to claim 4, wherein
said source consumption monitor monitors amounts of source consumed by the individual users; and
said charge collector calculates the charges based on the amounts of the consumed source and previously set unit price for the source, and collects the calculated charges from respective user's mediums.

9. A system for automatically collecting charges according to claim 5, wherein said charge collector includes a unit price setting area in which the unit price is set from an external device of said charge collector.

10. A system for automatically collecting charges according to claim 6, wherein said charge collector includes a unit price setting area in which the unit price is set from an external device of said charge collector.

11. A system for automatically collecting charges according to claim 7, wherein said charge collector includes a unit price setting area in which the unit price is set from an external device of said charge collector.

12. A system for automatically collecting charges according to claim 8, wherein said charge collector includes a unit price setting area in which the unit price is set from an external device of said charge collector.

13. A system for automatically collecting charges according to claim 9, wherein the unit price in said unit price setting area is set and updated by a provider of the source via a communication line.

14. A system for automatically collecting charges according to claim 10, wherein the unit price in said unit price setting area is set and updated by a provider of the source via a communication line.

15. A system for automatically collecting charges according to claim 11, wherein the unit price in said unit price setting area is set and updated by a provider of the source via a communication line.

16. A system for automatically collecting charges according to claim 12, wherein the unit price in said unit price setting area is set and updated by a provider of the source via a communication line.

17. A system for automatically collecting charges according to claim 1, further comprising one or more user's monitors, one provided for each user, for displaying at least one of the source consumption for the individual user, the charge in accordance with the source consumption, and the balance of electronic money stored in said user's medium for each said user, for monitoration by each said user.

18. A system for automatically collecting charges according to claim 1, further comprising a charge collector's monitor for displaying at least one of the source consumptions for the individual users, the charges in accordance with the individual source consumptions, and the balances of electronic money stored in said respective user's mediums, for monitoration by said charge collector.

19. A system for automatically collecting charges according to claim 1, further comprising a payment medium for storing the electronic money which has been collected from said user's mediums by said charge collector.

20. A system for automatically collecting charges according to claim 19, further comprising a collector's payment unit for receiving the electronic money, which has been stored in said payment medium.

21. A system for automatically collecting charges according to claim 20, wherein said collector's payment unit sends the electronic money, which has been received from said payment medium, to a provider of the source via a communication line.

22. A system for automatically collecting charges according to claim 20, further comprising a mobile terminal which includes a memory for receiving and storing the electronic money collected by said payment unit.

23. A terminal for automatically collecting charges in accordance with consumptions of a source from one or more users, wherein
said terminal is communicably connected with one or more user's mediums, provided one for each of the users, for storing electronic money, which is defined as an electronic alternative to a currency, and
said terminal is equipped with a charge collector for collecting the charges in accordance with the individual source consumptions from the respective user's mediums as corresponding equivalent amounts of electronic money.

24. A terminal for automatically collecting charges according to claim 23, further comprising a monitor for displaying at least one of the source consumptions for the individual users, the charges in accordance with the individual source consumptions, and the balances of electronic money stored in said respective user's mediums.
